(19) United States
(12) Patent Application Publication
(10) Pub. No.: US 2002/0197852 A1
(43) Pub. Date: Dec. 26, 2002

(54) Method of fabricating a barrier layer with high tensile strength

(76) Inventors: Ming-Shi Yeh, Chang-Hua Hsien (TW); Wen-Yi Hsieh, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/885,040

(22) Filed: Jun. 21, 2001

(51) Int. Cl. H01L 21/4763; H01L 21/44; H01L 21/31; H01L 21/469

(52) U.S. Cl. 438/638; 438/782; 438/781; 438/653

(57) ABSTRACT

A semiconductor wafer is provided, which has a low k layer positioned on the semiconductor wafer and a dual damascene structure positioned in the low k layer. The dual damascene structure includes a trench and a via hole, the via hole connecting to a conductive layer laid beneath. A barrier layer is formed at a temperature of 300 to 400° C. to cover the dual damascene structure and the low k layer. Thereafter, the semiconductor wafer is cooled to room temperature.

### BACKGROUND OF THE INVENTION

1. Field of the Invention

The present invention relates to a semiconductor process of fabricating an interconnection line, and more particularly, to a method of fabricating a barrier layer with high tensile strength to improve the reliability of a Cu dual damascene process.

2. Description of the Prior Art

To satisfy the requirements for high integration and high speed in integrated circuits (ICs), especially in a deep sub-micro (<0.18 μm) semiconductor process, a Cu dual damascene process is now becoming more widely used and a standard process in forming an interconnection line within the inter-metal dielectric (IMD) layer of low dielectric constant (k<3) materials. Since copper has both a low resistance and a low electromigration resistance, the low-k materials are useful to improve the RC delay effect of the metal interconnection.

Please refer to FIG. 1. FIG. 1 is a cross-sectional diagram of a semiconductor wafer 10 with a typical dual damascene structure 11. As shown in FIG. 1, the dual damascene structure 11, formed within a dielectric layer 20, is composed of a “via” (or a via hole) 22 and a trench 23. A conductive layer 14 is formed in a dielectric layer 12 beneath the via 22. A Cu conductive layer 24 fills the trench 23. A passivation layer 18 is positioned between the dielectric layers 12 and 20. A via plug 22a penetrates through the dielectric layer 20, the passivation layer 18 down to the surface of the dielectric layer 12, functioning to electrically connect the Cu conductive layer 24 to the conductive layer 14.

To prevent the diffusion of Cu from the dual damascene structure 11 into the adjacent dielectric layer 20, a barrier layer 25 is required on the surface of the dual damascene structure 11 according to the prior art. Commonly, the barrier layer 25 comprises the following properties: (1) good exclusion of the diffusing atoms, (2) good adhesion to Cu and the dielectric layer, (3) proper resistance (<1000 μΩ-cm), and (4) good step coverage. Usually Ti, TiN, TaN, WN, etc. are used to form the barrier layer.

However, failures such as a via open frequently occurs in the prior art Cu dual damascene process. Cu diffuses from cracks in the barrier layer 25 into the dielectric layer 20, which results in a disconnection problem between the Cu conductive layer 24 and the conductive layer 14. The situation is worsened when the dielectric layer 20 is composed of a low k material with a high thermal expansion coefficient, such as SiLK™ or a porous structure material. In a dual damascene process with a SiLK™ dielectric layer 20 and a TaN barrier layer 25, the thermal expansion coefficient of SiLK™, Cu and TaN are 60 ppm/° C., 17 ppm/° C. and 3 ppm/° C., respectively. The TaN barrier layer 25 with the least thermal expansion coefficient is subject to a thermal stress, thus producing cracking. As a result, so-called a via open failure is induced.

### SUMMARY OF THE INVENTION

It is therefore a primary objective of the present invention to provide a method for a dual damascene process to solve the above-mentioned problems.

It is another objective of the present invention to provide a method of fabricating a barrier layer with high tensile strength to improve the reliability of the dual damascene process.

In a preferred embodiment, the present invention provides a semiconductor wafer, which comprises a low k layer of SiLK™ with a dual damascene structure buried inside. The dual damascene structure comprises a trench and a via hole, the via hole connecting to a conductive layer laid beneath. A barrier layer is then formed on both the dual damascene structure and the low k layer of SiLK™.The barrier layer is formed by physical vapor deposition (PVD) in a temperature range from 300 to 400° C. The semiconductor wafer is thereafter cooled to room temperature. Therein, the low k layer has a first thermal expansion coefficient greater than the second thermal expansion coefficient of the barrier layer. For some embodiments, the first thermal expansion coefficient is greater than 50 ppm/° C. while the second thermal expansion coefficient is less than 10 ppm/° C.

In a second embodiment, the present invention process begins by providing a semiconductor wafer, which comprises a low k layer of SiLK™ with a dual damascene structure buried inside. The dual damascene structure comprises a trench and a via hole, the via hole connecting to a conductive layer laid beneath. Then, a barrier layer is formed on both the dual damascene structure and the low k layer of SiLK™. The barrier layer is formed at a temperature lower than 100° C. Thereafter, an adhesion layer is formed on the barrier layer using a PVD process at a temperature of approximately 300° C. followed by a cooling process to cool the semiconductor wafer to room temperature.

In a third embodiment, the present invention process begins by providing a semiconductor wafer, which comprises a low k layer of SiLK™ with a dual damascene structure buried inside. The dual damascene structure comprises a trench and a via hole, the via hole connecting to a conductive layer laid beneath. A barrier layer is formed on both the dual damascene structure and the low k layer of SiLK™. The barrier layer is formed at a temperature lower than 100° C. Thereafter, a CVD process is used to form a TiN layer on the barrier layer. During the CVD process of forming the TiN layer, the semiconductor wafer is heated to approximate 400° C. Subsequently, the semiconductor wafer is cooled to room temperature followed by the production of an adhesion layer of Ta on the TiN layer at room temperature.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 is a cross-sectional diagram of a dual damascene interconnection structure according to the prior art.

FIG. 2A to FIG. 2D are schematic diagrams of a first embodiment of the present invention.

FIG. 3A to FIG. 3D are schematic diagrams of a second embodiment of the present invention.

FIG. 4A to FIG. 4D are schematic diagrams of a third embodiment of the present invention.

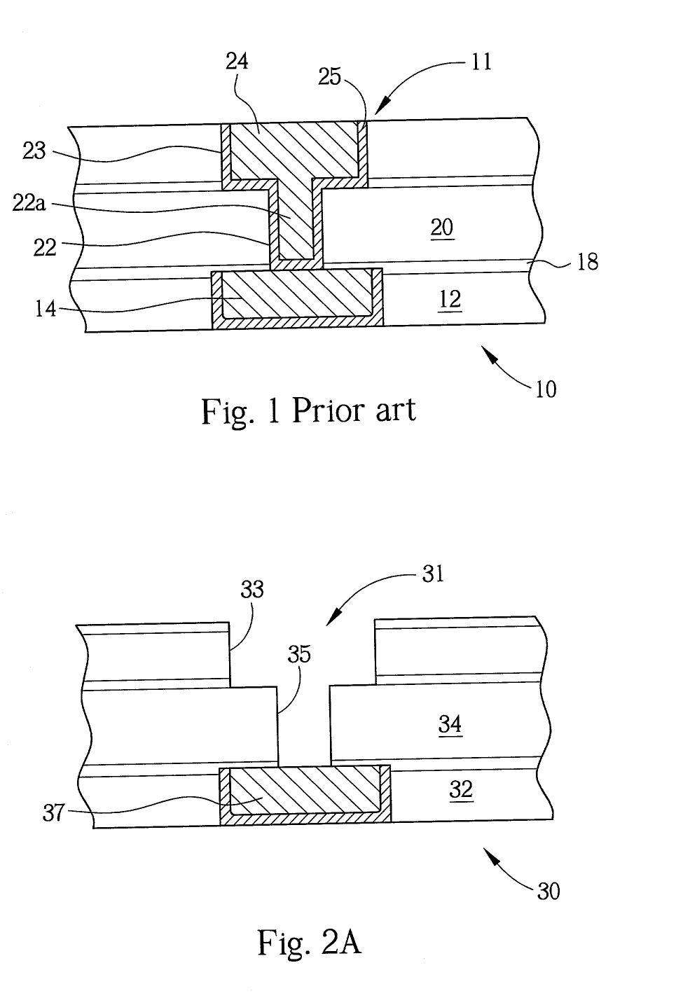

### DETAILED DESCRIPTION OF THE PREFERRED EMBODIMENT

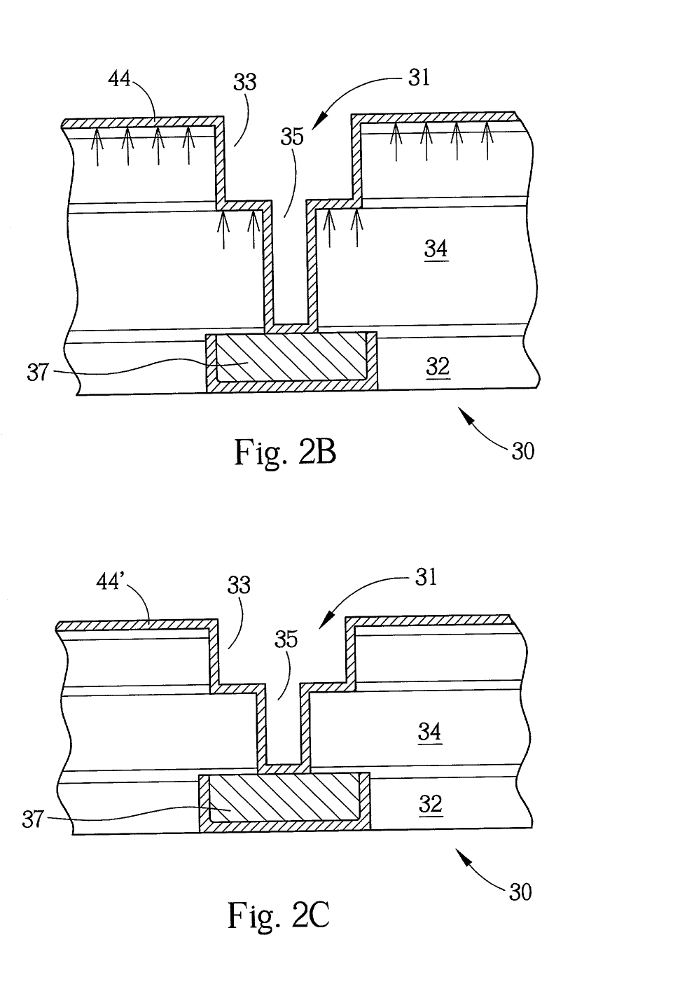

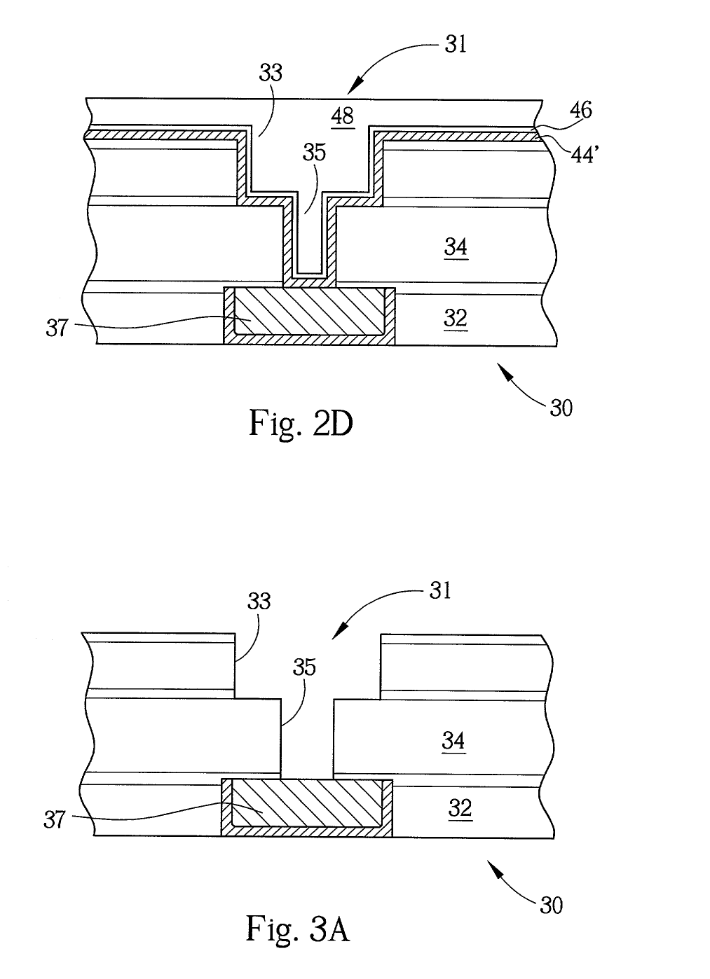

The first embodiment: a single barrier layer of TaN Please refer to FIG. 2A to FIG. 2D. FIG. 2A to FIG. 2D are cross-sectional views of a semiconductor wafer 30 according to the first embodiment of the present invention. First, as shown in FIG. 2A, the semiconductor wafer 30 comprises a substrate 32 and a low k layer 34 positioned on the substrate 32. The low k layer 34, such as a spin-on-coating (SOC) layer of FLARE™ or SiLK™, has a thermal expansion coefficient greater than that of the barrier layer formed thereafter. In this embodiment, the low k layer 34 is composed of SiLK™ and has a thermal expansion coefficient of 60 ppm/° C., which is approximate twenty times that of the thermal expansion coefficient of TaN. Alternatively, the low k layer 34 may be composed of organic materials, such as poly(arylene ether)polymer, parylene compounds, polyimide, fluorinated polyimide, HSQ, etc. The dielectric constant of the low k layer 34 ranges from 2.2 to 3.5, while the thickness of the low k layer 34 ranges from several thousands of angstroms to several micrometers.

The present invention process begins by forming a dual damascene structure 31 within the low k layer 34. The dual damascene structure 31 comprises a trench 33 and a via hole 35, the via hole 35 connecting to a conductive layer 37 in the substrate 32. The conductive layer 37 is composed of Cu. To emphasize the main feature of the present invention, the other elements in the substrate 32, such as other interconnecting lines, are not shown in FIG. 2A or other figures. The dual damascene structure 31 is formed by using a variety of Cu dual damascene processes, such as via-first, trench-first, buried etch stop or buried etch mask dual damascene process.

As shown in FIG. 2B, a barrier layer 44 is formed to cover the trench 33, the via hole 35 and the low k layer 34. In this embodiment, the barrier layer 44 may be composed of TaN, which has good adhesion to SiLK™. Alternatively, the barrier layer 44 is composed of TiN, TiW alloy, TaW alloy or their compositions. At a temperature between 300 to 400° C., physical vapor deposition (PVD) or high-density plasma physical vapor deposition (HDP PVD) is used to form the barrier layer 44 with a thickness between 100 to 600 angstroms. A preferred thickness of 150 to 400 angstroms is suggested for the barrier layer 44. Alternatively, the barrier layer 44 is formed by using a sputtering or chemical vapor deposition (CVD) process.

Since the barrier layer 44 is formed under a temperature of 300° C., the low k layer 34 incurs thermal expansion to lengthen the dual damascene structure 31. Hence, the barrier layer 44 is formed on the expanded surface of the dual damascene structure 31. Then, as shown in FIG. 2C, the semiconductor wafer 30 is cooled down to room temperature. During this process, the low k layer 34 reverts to its original thickness to become a pre-stressed barrier layer 44′. The pre-stressed barrier layer 44′ has a better tensile strength than the barrier layer 44 to overcome the thermal stress from the low k layer 34. As shown in FIG. 2D, a Cu seed layer 46 is formed on the surface of the pre-stressed barrier layer 44′. The Cu seed layer 46 is formed using a PVD process or other known processes. Subsequently, an electroless copper deposition (ECD) process is performed to fill the dual damascene structure 31 with a Cu layer 48. After the deposition of the Cu layer 48, a chemical mechanical polishing (CMP) removes a portion of the Cu layer 48, leaving the Cu layer 48 in the trench 33 and the via hole 35 intact. Since the features of the present invention focus on the treatments on the barrier layer 44 and the formation process of the pre-stressed barrier layer 44′, the subsequent steps for forming the Cu interconnections are not described here.

The second embodiment: a dual-layer barrier layer of TaN/Ta

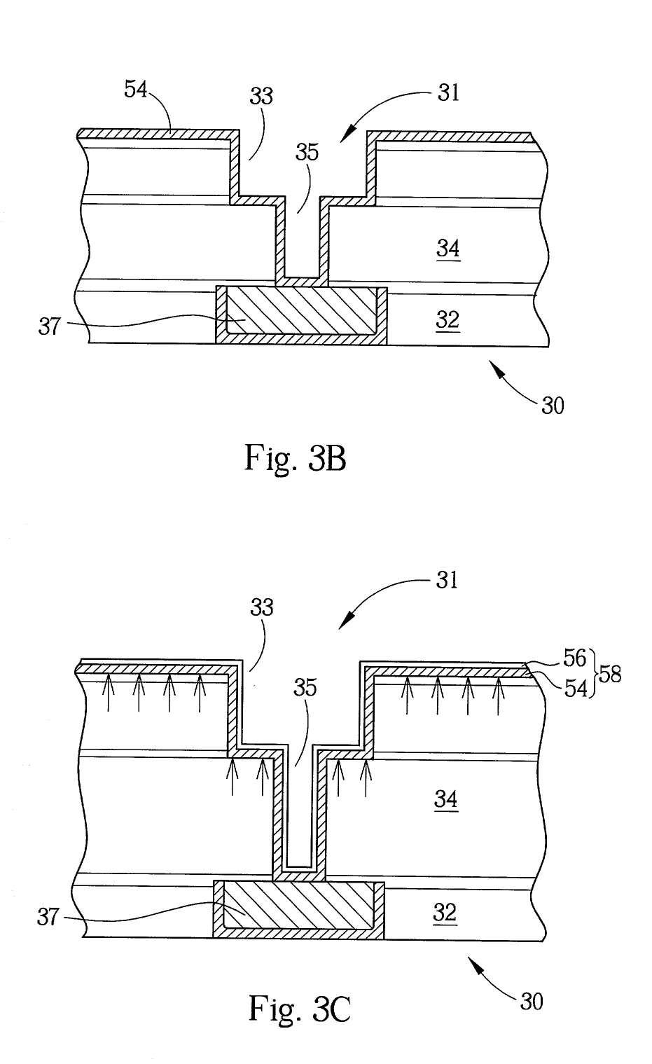

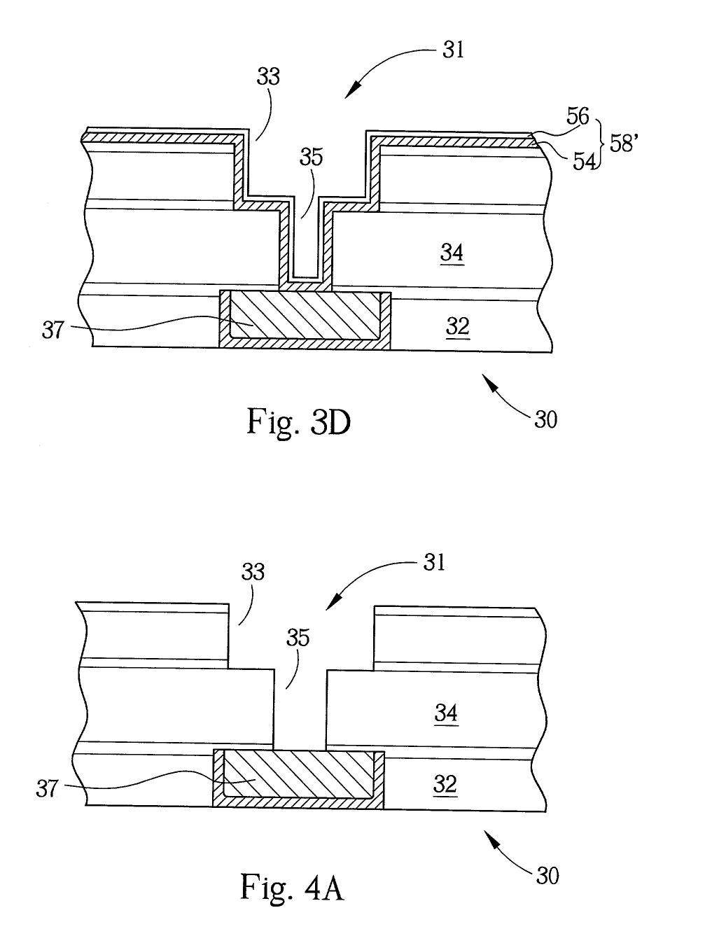

Please refer to FIG. 3A to FIG. 3D. FIG. 3A to FIG. 3D are cross-sectional views of a semiconductor wafer 30 according to the second embodiment of the present invention. As shown in FIG. 3A, the semiconductor wafer 30 comprises a substrate 32, a low k layer 34 positioned on the substrate 32 and a dual damascene structure 31 formed within the low k layer 34. The dual damascene structure 31 comprises a trench 33 and a via hole 35, the via hole 35 connecting to a conductive layer 37 in the substrate 32. The low k layer 34 has a thermal expansion coefficient greater than that of the barrier layer formed thereafter.

The dual damascene structure 31 is created by using a variety of Cu dual damascene processes, such as via-first, trench-first, buried etch stop or buried etch mask dual damascene processes. In this embodiment, the low k layer 34 is composed of SiLK™. Alternatively, the low k layer 34 may be composed of organic materials, such as poly (arylene ether) polymer, parylene compounds, polyimide, fluorinated polyimide, HSQ, etc.

As shown in FIG. 3B, a barrier layer 54 is formed thereafter to cover the trench 33, the via hole 35 and the low k layer 34. In this second embodiment, the barrier layer 54 is composed of TaN, which has good adhesion to SiLK™. Alternatively, the barrier layer 54 is composed of TiN, TiW alloy, TaW alloy or their compositions. At a temperature below 100° C., a physical vapor deposition (PVD) or high-density plasma PVD process is employed to form the barrier layer 54 with a thickness between 100 to 600 angstroms. A preferred thickness of the barrier layer 54 is 150 to 400 angstroms. Alternatively, the barrier layer 54 may be formed using a sputtering or chemical vapor deposition (CVD) process.

Next, as shown in FIG. 3C, a PVD or HDP PVD process is performed at a temperature of approximate 300° C. to form an adhesion layer 56 on the surface of the barrier layer 54. The barrier layer 54 combines the adhesion layer 56 to form a dual-layer barrier layer 58. In this second embodiment, the adhesion layer 56 is composed of Ta. Since the adhesion layer 56 is formed under a thermal (300° C.) environment, the low k layer 34 incurs thermal expansion to lengthen the dual damascene structure 31 as well as to induce cracking in the barrier layer 54. However, during the fabricating process of the adhesion layer 56, Ta atoms from the adhesion layer 56 will diffuse into the cracks to repair the structure of the barrier layer 54.

Thereafter, as shown in FIG. 3D, the semiconductor wafer 30 is cooled to room temperature. During this process, the low k layer 34 reverts to its original thickness to become a pre-stressed dual-layer barrier layer 58′. The pre-stressed dual-layer barrier layer 58′ has a better tensile strength than the barrier layer 58 to overcome the thermal stress from the low k layer 34. In addition, further steps are included but not shown here, to finish the fabrication of the Cu dual damascene process, including: (1) forming a Cu seed layer on the surface of the pre-stressed barrier layer 58′, (2) performing an electroless copper deposition (ECD) process to fill a Cu layer within the dual damascene structure 31, and (3) performing a CMP process to remove the Cu layer outside the dual damascene structure 31.

The third embodiment: a multi-layer barrier layer of TaN/CVD-TiN/Ta

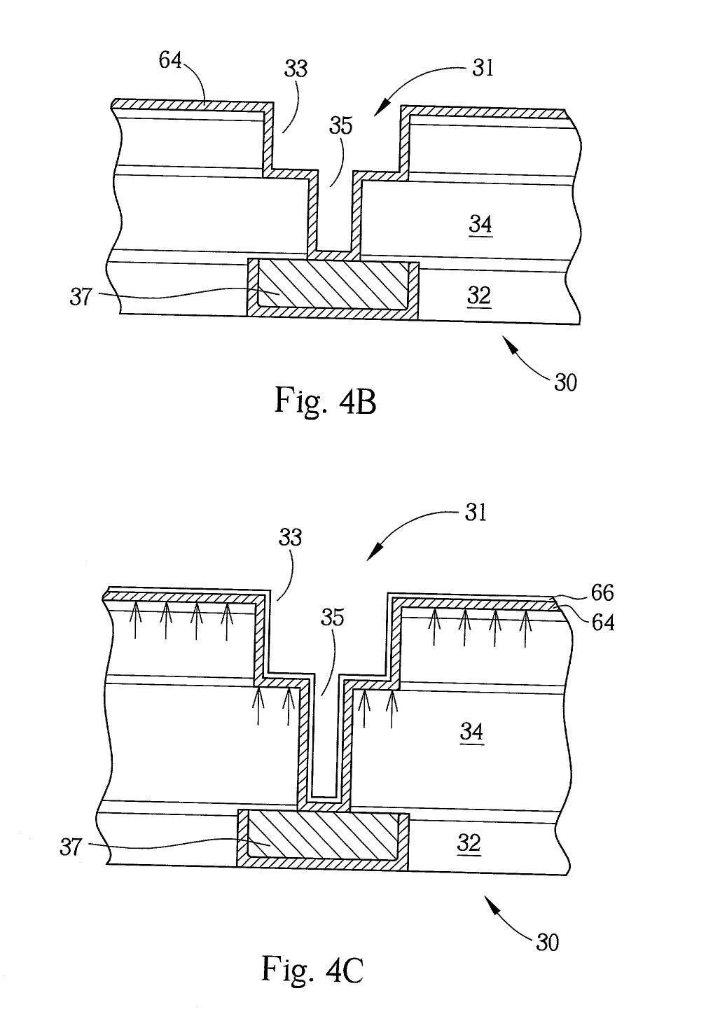

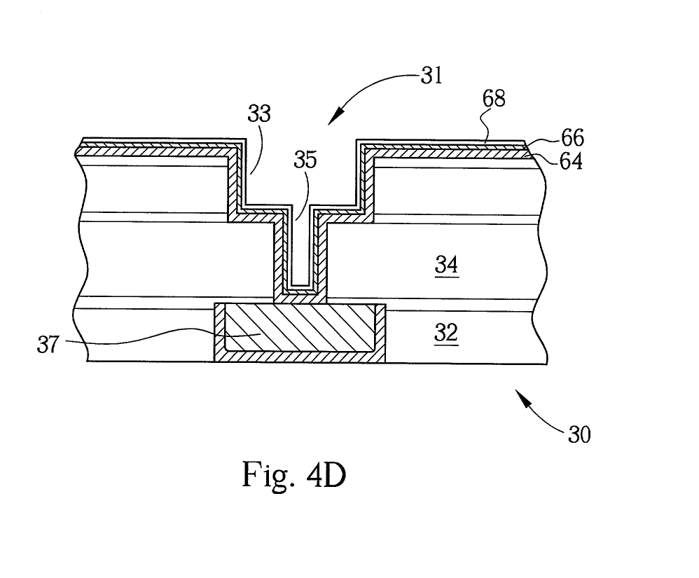

Please refer to FIG. 4A to FIG. 4D. FIG. 4A to FIG. 4D show cross-sectional views of a semiconductor wafer 30 of the third embodiment of the present invention. As shown in FIG. 4A, the semiconductor wafer 30 comprises a substrate 32, a low k layer 34 positioned on the substrate 32 and a dual damascene structure 31 formed within the low k layer 34. The dual damascene structure 31 comprises a trench 33 and a via hole 35, the via hole 35 connecting to a conductive layer 37 in the substrate 32. The low k layer 34 has a thermal expansion coefficient greater than that of the barrier layer formed thereafter.

The dual damascene structure 31 is formed by using a variety of Cu dual damascene processes, including via-first, trench-first, buried etch stop or buried etch mask dual damascene processes. In this embodiment, the low k layer 34 is composed of SiLK™. Alternatively, the low k layer 34 is composed of organic materials, such as poly (arylene ether) polymer, parylene compounds, polyimide, fluorinated polyimide, HSQ, etc.

As shown in FIG. 4B, a barrier layer 64 is formed thereafter to cover the trench 33, the via hole 35 and the low k layer 34. In this third embodiment, the barrier layer 64 is composed of TaN, which has good adhesion to SiLK™. At a temperature below 100° C., a physical vapor deposition (PVD) or high-density plasma PVD process functions to form the barrier layer 64 with a thickness between 100 to 600 angstroms. A preferred thickness of the barrier layer 64 is 150 to 400 angstroms. Alternatively, the barrier layer 64 maybe formed using a sputtering or chemical vapor deposition (CVD) process.

Then, as shown in FIG. 4C, a CVD process is performed to deposit a TiN layer 66 on the surface of the barrier layer 64. During the deposition process of the TiN layer 66, the semiconductor wafer 30 is heated to approximately 400° C. Under such a temperature, the low k layer 34 incurs thermal expansion to lengthen the dual damascene structure 31 as well as to induce cracking in the barrier layer 64 positioned within the dual damascene structure 31. However, the TiN layer 66 repairs the cracks.

Thereafter, as shown in FIG. 4D, the semiconductor wafer 30 is cooled to room temperature. During this process, both the barrier layer 64 and the TiN layer 66 are pre-stressed as a result of the low k layer 34 reverting back to its original thickness. An adhesion layer 68 of Ta is formed on the surface of the TiN layer 66 at room temperature. In addition, further steps are included but not shown to finish the fabrication of the Cu dual damascene process, including: (1) forming a Cu seed layer on the surface of the adhesion layer 68, (2) performing an electroless copper deposition (ECD) process to fill a Cu layer within the dual damascene structure 31, and (3) performing a CMP process to remove the Cu layer outside the dual damascene structure 31.

Generally speaking, the TiN layer 66 is formed under a pressure of 1˜10 mTorr, and uses a magnetic DC sputtering method with argon (Ar) gas as a plasma gas. Alternatively, a TDMAT or TEMAT is used as a precursor to perform a thermal reaction under a temperature of 300 to 420° C. and a pressure between 0.5 and 2.0 mTorr, resulting in a TiN layer being deposited with a resistance of 300 μohm/cm. Alternatively, TiCl₄ and NH₃ are used as the precursors to achieve the thermal reaction at 630 to 700° C., so depositing a TiN layer of 80% step coverage with a resistance of 200 μohm/cm.

In contrast to the prior art, the method of the present invention uses a varying temperature during the fabricating process of the barrier, thus providing a pre-stress on the barrier layer to enhance the tensile strength. Hence, the barrier layer efficiently prevents the diffusion of the Cu atoms to improve the reliability of the dual damascene process.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method to improve the reliability of a dual damascene process, the method comprising:
providing a semiconductor wafer having a spin-on-coating (SOC) dielectric layer and a dual damascene structure in the SOC dielectric layer, the dual damascene structure comprising both a trench and a via hole;
heating the semiconductor wafer to a predetermined temperature to form a barrier layer on the surface of the dual damascene structure, wherein the SOC dielectric layer incurs thermal expansion at the predetermined temperature; and
cooling both the semiconductor wafer and the barrier layer to produce a pre-stress on the barrier layer;
wherein the SOC dielectric layer has a first thermal expansion coefficient greater than a second thermal expansion coefficient of the barrier layer.

2. The method of claim 1 wherein the SOC layer is composed of SiLK™.

3. The method of claim 1 wherein the predetermined temperature ranges from 300 to 400° C.

4. The method of claim 1 wherein the first thermal expansion coefficient is greater than 50 ppm/° C.

5. The method of claim 1 wherein the second thermal expansion coefficient is less than 10 ppm/C.

6. The method of claim 1 wherein both the semiconductor and the barrier layer are cooled to room temperature.

7. The method of claim 1 wherein the barrier layer is composed of TaN.

8. The method of claim 7 wherein the barrier layer is formed by a physical vapor deposition (PVD) process.

9. The method of claim 1 wherein after cooling both the semiconductor wafer and the barrier layer the method further comprises:
forming a copper (Cu) seed layer on the barrier layer;
depositing a copper layer on the copper seed layer to fill both the trench and the via hole;
performing a chemical mechanical polishing (CMP) process to leave copper within the dual damascene structure; and
forming a passivation layer on the copper.

10. A method of fabricating a dual damascene interconnection, the method comprising:
providing a semiconductor wafer having a low dielectric constant (low k) layer;
forming a dual damascene structure in the low k layer, the dual damascene structure comprising both a trench and a via hole;
forming a barrier layer on the surface of the dual damascene structure at a first predetermined temperature;
heating the semiconductor wafer to a second predetermined temperature to form an adhesion layer on the surface of the barrier layer, wherein the second predetermined temperature is higher than the first predetermined temperature to induce thermal expansion of the low k layer as well as to produce cracking of the barrier layer; and
cooling the semiconductor wafer and the barrier/adhesion layer to produce a pre-stress on the barrier/adhesion layer;
wherein the low k layer has a first thermal expansion coefficient greater than a second thermal expansion coefficient of the barrier layer.

11. The method of claim 10 wherein the low k layer is composed of SiLK™.

12. The method of claim 10 wherein the first predetermined temperature is less than 100° C.

13. The method of claim 10 wherein the second predetermined temperature ranges from 300 to 400° C.

14. The method of claim 10 wherein the semiconductor and the barrier/adhesion layer are cooled to room temperature.

15. The method of claim 10 wherein the barrier layer is composed of TaN and the adhesion layer is composed of Ta.

16. A method of fabricating a dual damascene interconnection, the method comprising:
providing a semiconductor wafer having a spin-on-coating (SOC) dielectric layer;
forming a dual damascene structure in the SOC dielectric layer, the dual damascene structure comprising both a trench and a via hole;
forming a barrier layer on the surface of the dual damascene structure at a first predetermined temperature;
heating the semiconductor wafer to a second predetermined temperature to form a TiN layer on the surface of the barrier layer, wherein the second predetermined temperature is higher than the first predetermined temperature to induce thermal expansion of the SOC dielectric layer as well as to produce cracking of the barrier layer; and
cooling the semiconductor wafer and the barrier/TiN layer to a third predetermined temperature to produce a pre-stress on the barrier/TiN layer, followed by coverage of an adhesion layer on the TiN layer;
wherein the SOC dielectric layer has a first thermal expansion coefficient greater than a second thermal expansion coefficient of the barrier layer.

17. The method of claim 16 wherein the SOC dielectric layer is composed of SiLK™.

18. The method of claim 16 wherein the first predetermined temperature is less than 100° C.

19. The method of claim 16 wherein the second predetermined temperature ranges from 300 to 400° C., and the third predetermined temperature is room temperature.

20. The method of claim 16 wherein the barrier layer is composed of TaN and the adhesion layer is composed of Ta.
